(19) United States
(12) Patent Application Publication
(10) Pub. No.: US 2012/0273826 A1
(43) Pub. Date: Nov. 1, 2012

(54) LED PACKAGE AND METHOD FOR MANUFACTURING SAME

(75) Inventors: Mami Yamamoto, Fukuoka-ken (JP); Kazuhiro Inoue, Fukuoka-ken (JP); Satoshi Shimizu, Fukuoka-ken (JP); Hidenori Egoshi, Fukuoka-ken (JP); Yasunori Nagahata, Fukuoka-ken (JP)

(73) Assignee: KABUSHIKI KAISHA TOSHIBA, Tokyo (JP)

(21) Appl. No.: 13/234,792

(22) Filed: Sep. 16, 2011

(30) Foreign Application Priority Data
Apr. 28, 2011 (JP) 2011-102226

(51) Int. Cl. H01L 33/36; H01L 33/52

(52) U.S. Cl. 257/99; 438/28; 257/E33.062; 257/E33.059

(57) ABSTRACT

According to one embodiment, an LED package includes a first leadframe and a second leadframe mutually-separated, an LED chip and a resin body. The LED chip is provided above the first and second leadframes. One terminal of the LED chip is connected to the first leadframe. One other terminal is connected to the second leadframe. The resin body covers an entire upper surface, a portion of a lower surface, and a portion of an end surface of each of the first and second leadframes. The resin body covers the LED chip. Remaining portions of the lower surface and the end surface of each of the first and second leadframes are exposed on the resin body. First and second recesses are made between the remaining portions of the first and second leadframes. An inner surface of each of the first and second recesses is not covered with the resin body.

### CROSS-REFERENCE TO RELATED APPLICATIONS

This application is based upon and claims the benefit of priority from the prior Japanese Patent Application No. 2011-102226, filed on Apr. 28, 2011; the entire contents of which are incorporated herein by reference.

### FIELD

Embodiments described herein relate generally to an LED (Light Emitting Diode) package and a method for manufacturing the same.

### BACKGROUND

In a conventional LED package in which an LED chip is mounted, a casing having a bowl-like configuration made of a white resin is provided, the LED chip is mounted on the bottom surface of the casing, and the LED chip is buried in the interior of the casing by encapsulating with a transparent resin to control the light distribution properties and increase the extraction efficiency of the light from the LED package. Often, casings have been formed of a polyamide-based thermoplastic resin.

However, in recent years, higher durability is needed for LED packages as the range of applications of LED packages increases. On the other hand, the light and the heat radiated from the LED chip increase as the output of the LED chip increases; and degradation of the resin portion that seals the LED chip progresses easily. Further, even lower costs are needed as the range of applications of LED packages increases.

### BRIEF DESCRIPTION OF THE DRAWINGS

FIG. 1 is a perspective view illustrating an LED package according to a first embodiment;

FIG. 2 is a side view illustrating the LED package according to the first embodiment;

FIG. 3 is a plan view illustrating leadframes of the LED package according to the first embodiment;

FIGS. 4A to 4H are cross-sectional views of processes, illustrating a method for forming the leadframe sheet of the embodiment;

FIG. 5A is a plan view illustrating the leadframe sheet of the first embodiment; and FIG. 5B is a partially-enlarged plan view illustrating device regions of the leadframe sheet;

FIG. 6 is a flowchart illustrating a method for manufacturing the LED package according to the first embodiment;

FIGS. 7A to 7C are cross-sectional views of processes, illustrating the method for manufacturing the LED package according to the first embodiment;

FIGS. 8A to 8F are cross-sectional views of processes, illustrating a wire bonding method of the first embodiment;

FIGS. 9A to 9C are cross-sectional views of processes, illustrating the method for manufacturing the LED package according to the first embodiment;

FIGS. 10A and 10B are cross-sectional views of processes, illustrating the method for manufacturing the LED package according to the first embodiment;

FIG. 11 is a perspective view illustrating an LED package according to a second embodiment;

FIG. 12 is a side view illustrating the LED package according to the second embodiment;

FIG. 13 is a perspective view illustrating an LED package according to a third embodiment;

FIG. 14 is a side view illustrating the LED package according to the third embodiment;

FIG. 15 is a perspective view illustrating an LED package according to a fourth embodiment;

FIG. 16 is a side view illustrating the LED package according to the fourth embodiment;

FIG. 17 is a perspective view illustrating an LED package according to the fifth embodiment;

FIG. 18 is a side view illustrating the LED package according to the fifth embodiment;

FIG. 19 is a perspective view illustrating an LED package according to the sixth embodiment;

FIG. 20 is a side view illustrating the LED package according to the sixth embodiment;

FIG. 21 is a perspective view illustrating an LED package according to a seventh embodiment; and

FIG. 22 is a side view illustrating the LED package according to the seventh embodiment.

### DETAILED DESCRIPTION

In general, according to one embodiment, an LED package includes a first leadframe and a second leadframe mutually-separated, an LED chip and a resin body. The LED chip is provided above the first leadframe and the second leadframe. One terminal of the LED chip is connected to the first leadframe. One other terminal of the LED chip is connected to the second leadframe. The resin body covers an entire upper surface, a portion of a lower surface, and a portion of an end surface of the first leadframe, and an entire upper surface, a portion of a lower surface, and a portion of an end surface of the second leadframe. The resin body covers the LED chip. A remaining portion of the lower surface of the first leadframe and a remaining portion of the end surface of the first leadframe are exposed on the resin body. A remaining portion of the lower surface of the second leadframe and a remaining portion of the end surface of the second leadframe are exposed on the resin body. A first recess is made between the remaining portion of the lower surface of the first leadframe and the remaining portion of the end surface of the first leadframe. A second recess is made between the remaining portion of the lower surface of the second leadframe and the remaining portion of the end surface of the second leadframe. An inner surface of each of the first recess and the second recess is not covered with the resin body.

In general, according to one embodiment, a method is disclosed for manufacturing an LED package. The method can include forming a leadframe sheet. The leadframe sheet is made of a conductive material and includes a plurality of device regions arranged in a matrix configuration. A basic pattern including a first leadframe and the second leadframe mutually-separated is formed in each of the device regions. A plurality of linking portions are provided in a dicing region between the device regions to extend from the basic pattern through the dicing region to the basic pattern of an adjacent device region. A recess is made in a lower surface of each of the linking portions. The method can include adhering a reinforcing tape to a lower surface of the leadframe sheet to cover the recess. The method can include mounting an LED chip on an upper surface of the leadframe sheet in each of the device regions, connecting one terminal of the LED chip to the first leadframe, and connecting one other terminal of the LED chip to the second leadframe. The method can include causing the upper surface of the leadframe sheet to contact a liquid or semi-liquid resin held by a template to cause the resin to enter a gap made by removing the conductive material. The gap does not include the recess. The method can include forming a resin plate by curing the resin. The method can include peeling the reinforcing tape from the leadframe sheet. In addition, the method can include dividing the recess while singulating portions of the leadframe sheet and the resin plate disposed in the device region by cutting portions of the leadframe sheet and the resin plate disposed in the dicing region.

Various embodiments will be described hereinafter with reference to the accompanying drawings.

First, a first embodiment will be described.

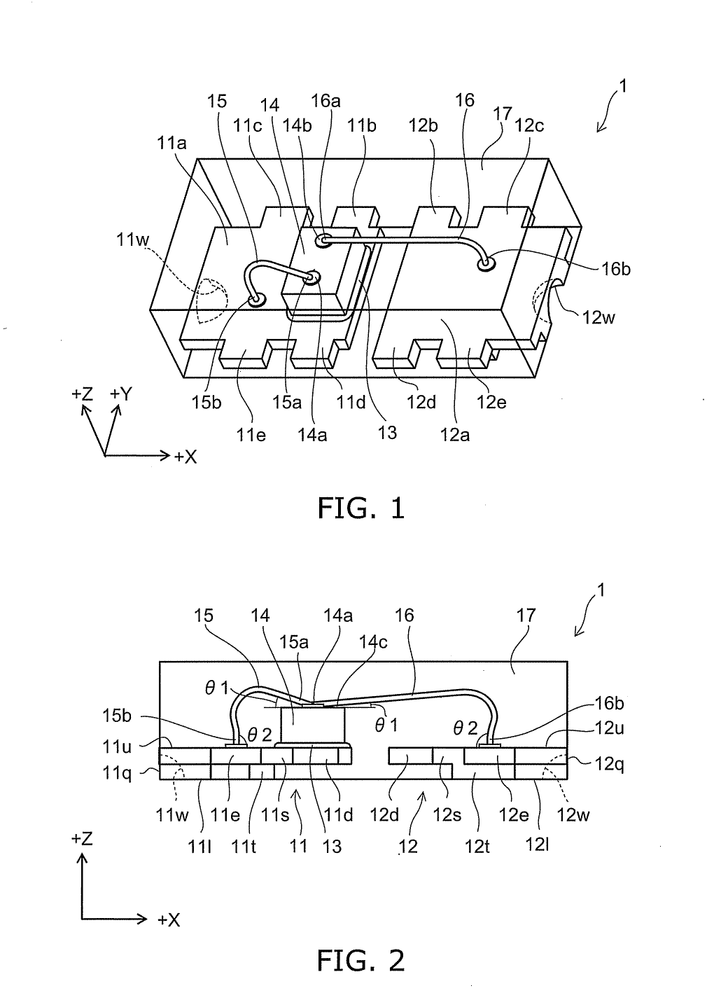

FIG. 1 is a perspective view illustrating an LED package according to the embodiment.

FIG. 2 is a side view illustrating the LED package according to the embodiment.

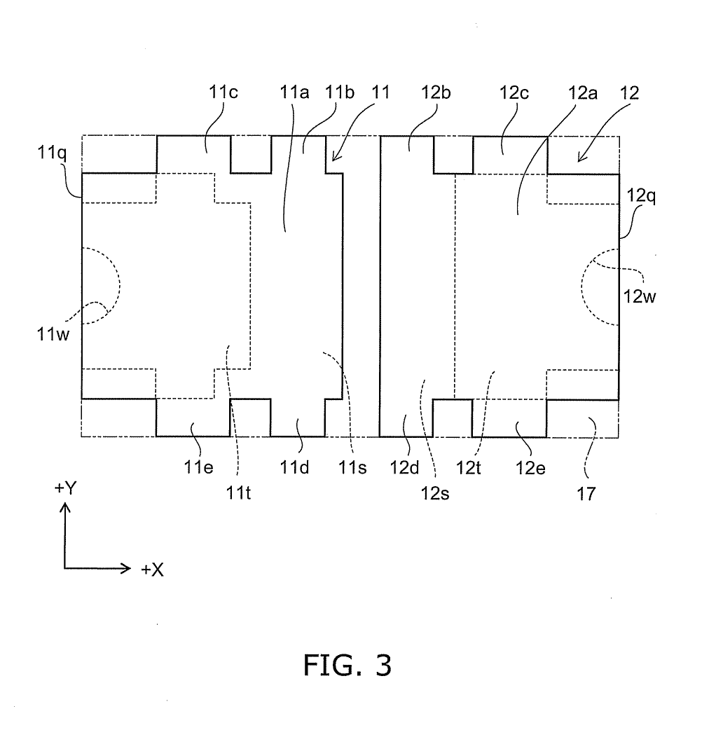

FIG. 3 is a plan view illustrating leadframes of the LED package according to the embodiment.

As illustrated in FIG. 1 to FIG. 3, a pair of leadframes 11 and 12 are provided in the LED package 1 according to the embodiment. The leadframes 11 and 12 have flat plate configurations, are disposed on the same plane, and are separated from each other.

Hereinbelow, for convenience of description in the specification, an XYZ orthogonal coordinate system is introduced. A direction parallel to the upper surfaces of the leadframes 11 and 12 from the leadframe 11 toward the leadframe 12 is taken as a +X direction. An upward direction perpendicular to the upper surfaces of the leadframes 11 and 12, that is, the direction in which an LED chip 14 is mounted as viewed from the leadframes, is taken as a +Z direction. One direction orthogonal to both the +X direction and the +Z direction is taken as a +Y direction. The directions opposite to the +X direction, the +Y direction, and the +Z direction are taken as a −X direction, a −Y direction, and a −Z direction, respectively. The +X direction and the −X direction, for example, also are generally referred to as simply the X direction.

The configuration of the leadframe 11 as viewed from above (the +Z direction) is a configuration in which four extending portions 11b to 11e extend from a rectangular base portion 11a. The extending portions 11b and 11c extend toward the +Y direction from the end edge of the base portion 11a facing the +Y direction; and the extending portion 11b is positioned on the +X direction side of the extending portion 11c. The extending portion 11b extends from a portion of the base portion 11a that is proximal to the end portion of the base portion 11a on the +X direction side and slightly separated from the end edge of the base portion 11a facing the +X direction; and the extending portion 11c extends from a proximity of the X-direction central portion of the base portion 11a. The extending portions 11d and 11e extend toward the −Y direction from the end edge of the base portion 11a facing the −Y direction; and the extending portion 11d is positioned on the +X direction side of the extending portion 11e. In the X direction, the position of the extending portion 11d is the same as the position of the extending portion 11b; and the position of the extending portion 11e is the same as the position of the extending portion 11c.

The leadframe 11 includes a thick plate portion lit and a thin plate portion 11s as viewed from the side (the X direction and the Y direction). In the Z direction, the upper surface of the thick plate portion 11t and the upper surface of the thin plate portion 11s are at the same position; and the lower surface of the thick plate portion 11t is lower than the lower surface of the thin plate portion 11s. Accordingly, the thin plate portion 11s is thinner than the thick plate portion 11t. The base portion 11a includes the entire thick plate portion 11t and a portion of the thin plate portion 11s; and the end portion of the base portion 11a on the leadframe 12 side, i.e., the end portion on the +X direction side, is the thin plate portion 11s. The configuration of the thick plate portion 11t is cross-shaped as viewed from the Z direction. The extending portions 11b to 11e are the remaining portions of the thin plate portion 11s.

A recess 11w is made in the lower portion of the Y-direction central portion of the end portion of the leadframe 11 on the side opposite to the leadframe 12, i.e., the end portion on the −X direction side, by causing an end surface 11q facing the −X direction and a lower surface 11l to recede toward the +X/+Z direction. The recess 11w is made between the lower surface 11l of the thick plate portion 11t and the end surface 11q of the base portion 11a and does not reach an upper surface 11u of the leadframe 11. The configuration of the recess 11w is, for example, a portion of a sphere, e.g., one quarter of a sphere. However, the configuration of the recess 11w is not limited to a portion of a spherical body. As described below, it is sufficient for a plating layer to be formed and for there to be an affinity to the bonding material such as solder, etc., during the mounting. For example, the configuration of the recess 11w may be a rectangular parallelepiped or a portion of a circular column.

On the other hand, the configuration of the leadframe 12 is substantially the configuration of the leadframe 11 inverted around the YZ plane.

The configuration of the leadframe 12 as viewed from above (the +Z direction) is a configuration in which four extending portions 12b to 12e are extended from a rectangular base portion 12a. The extending portions 12b and 12c extend toward the +Y direction from the end edge of the base portion 12a facing the +Y direction; and the extending portion 12b is positioned on the −X direction side of the extending portion 12c. The extending portion 12b extends from a portion of the base portion 12a contacting the end edge of the base portion 12a facing the −X direction; and the extending portion 12c extends from a proximity of the X-direction central portion of the base portion 12a. The extending portions 12d and 12e extend toward the −Y direction from the end edge of the base portion 12a facing the −Y direction; and the extending portion 12d is positioned on the −X direction side of the extending portion 12e. In the X direction, the position of the extending portion 12d is the same as the position of the extending portion 12b; and the position of the extending portion 12e is the same as the position of the extending portion 12c.

Similarly to the leadframe 11, the leadframe 12 also includes a thick plate portion 12t and a thin plate portion 12s. In the Z direction, the upper surface of the thick plate portion 12t and the upper surface of the thin plate portion 12s are at the same position; and the lower surface of the thick plate portion 12t is lower than the lower surface of the thin plate portion 12s. Accordingly, the thin plate portion 12s is thinner than the thick plate portion 12t. The base portion 12a includes the entire thick plate portion 12t and a portion of the thin plate portion 12s; and the end portion of the base portion 12a on the leadframe 11 side, i.e., the end portion on the −X direction side, is the thin plate portion 12s. In other words, the mutually-opposing portions of the leadframes 11 and 12 include the thin plate portions 11s and 12s. The configuration of the thick plate portion 12t is T-shaped as viewed from the Z direction. The extending portions 12b to 12e are the remaining portions of the thin plate portion 12s.

A recess 12w is made in the lower portion of the Y-direction central portion of the end portion of the leadframe 12 on the side opposite to the leadframe 11, i.e., the end portion on the +X direction side, by causing a lower surface 12l and an end surface 12q facing the +X direction of the leadframe 12 to recede toward the −X/+Z direction. The recess 12w is made in the base portion 12a between the end surface 12q and the lower surface 121 of the thick plate portion 12t and does not reach an upper surface 12u of the leadframe 12. The configuration of the recess 12w is, for example, a portion of a sphere, e.g., one quarter of a sphere. However, the configuration of the recess 12w is not limited to a portion of a spherical body. As described below, it is sufficient for a plating layer to be formed and for there to be an affinity to the bonding material such as solder, etc., during the mounting. For example, the configuration of the recess 11w may be a rectangular parallelepiped or a portion of a circular column.

In the leadframes 11 and 12, a plating layer made of one other conductive material is formed on a portion of the surface of a main body made of one conductive material. For example, the main bodies of the leadframes 11 and 12 are formed of copper (Cu). Then, the upper surface 11u, the lower surface 11l, and the inner surface of the recess 11w of the leadframe 11 and the upper surface 12u, the lower surface 12l, and the inner surface of the recess 12w of the leadframe 12 are covered with a plating layer made of the same conductive material. On the other hand, the end surfaces of the leadframes 11 and 12 are not covered with this plating layer. In the case where the main bodies of the leadframes 11 and 12 are made of copper, the plating layer is made of, for example, silver (Ag) or palladium (Pd).

A die mount material 13 is bonded to cover the region positioned at the Y-direction central portion of the upper surface 11u of the leadframe 11 at the end portion on the +X direction side, i.e., the upper surface of the portion of the base portion 11a between the extending portion 11b and the extending portion 11d. In the embodiment, the die mount material 13 may be conductive or insulative. In the case where the die mount material 13 is conductive, the die mount material 13 is formed of, for example, a silver paste, solder, eutectic solder, etc. In the case where the die mount material 13 is insulative, the die mount material 13 is formed of, for example, a transparent resin paste.

The LED chip 14 is provided on the die mount material 13. The LED chip 14 is mounted to the leadframe 11 by the die mount material 13 affixing the LED chip 14 to the leadframe 11. The LED chip 14 includes, for example, a semiconductor layer made of gallium nitride (GaN), etc., stacked on a sapphire substrate; the configuration thereof is, for example, a rectangular parallelepiped; and terminals 14a and 14b are provided on the upper surface thereof. The LED chip 14 is configured to emit, for example, blue light by a voltage being supplied between the terminal 14a and the terminal 14b.

One end portion 15a of a wire 15 is bonded to the terminal 14a of the LED chip 14; and the other end portion 15b of the wire 15 is bonded to the upper surface 11u of the leadframe 11. Thereby, the terminal 14a is connected to the leadframe 11 via the wire 15. On the other hand, one end portion 16a of a wire 16 is bonded to the terminal 14b; and the other end portion 16b of the wire 16 is bonded to the upper surface 12u of the leadframe 12. Thereby, the terminal 14b is connected to the leadframe 12 via the wire 16. The bonding portion between the wire 15 and the leadframe 11 is positioned on the thick plate portion 11t; and the bonding portion between the wire 16 and the leadframe 12 is positioned on the thick plate portion 12t. The wires 15 and 16 are formed of a metal, e.g., gold or aluminum.

The end portion 15a of the wire 15 is drawn out obliquely upward (the −X/+Z direction) from the terminal 14a; and the end portion 15b is drawn out in a substantially perpendicular direction (the +Z direction) from the upper surface 11u. In other words, an angle (a chip-side draw-out angle) θ1 between an upper surface 14c (the XY plane) of the LED chip 14 and the direction (the −X/+Z direction) in which the wire 15 is drawn out from the terminal 14a is smaller than an angle (a frame-side draw-out angle) θ2 between the upper surface 11u (the XY plane) of the leadframe 11 and the direction (substantially the +Z direction) in which the wire 15 is drawn out from the leadframe 11. On the other hand, the end portion 16a of the wire 16 is drawn out in a substantially horizontal direction (the +X direction) from the terminal 14b; and the end portion 16b is drawn out in a substantially perpendicular direction (the +Z direction) from an upper surface 12h of the leadframe 12. Therefore, for the wire 16 as well, the chip-side draw-out angle θ1 at which the end portion 16a is drawn out from the terminal 14b is smaller than the frame-side draw-out angle θ2 at which the end portion 16b is drawn out from the leadframe 12.

A transparent resin body 17 is provided in the LED package 1. The transparent resin body 17 is formed of a transparent resin, e.g., a silicone resin. “Transparent” also includes being semi-transparent. The exterior form of the transparent resin body 17 is a substantially rectangular parallelepiped that covers the leadframes 11 and 12, the die mount material 13, the LED chip 14, and the wires 15 and 16; and the exterior form of the transparent resin body 17 substantially is used as the exterior form of the LED package 1. In the specification, the concept of covering includes both the case of the covering component being in contact with the covered component and the case of not being in contact.

The entire upper surfaces of the leadframes 11 and 12 are covered with the transparent resin body 17. The lower surfaces of the thick plate portions 11t and 12t of the leadframes 11 and 12 are exposed on the lower surface of the transparent resin body 17; and the lower surfaces of the thin plate portions 11s and 12s are covered with the transparent resin body 17. The tip surfaces of the extending portions of the leadframes 11 and 12 are exposed on the side surfaces of the transparent resin body 17 facing the Y direction; and the side surfaces of the extending portions are covered with the transparent resin body 17. The end surface of the base portion 11a facing the +X direction and the end surface of the base portion 12a facing the −X direction are covered with the transparent resin body 17. The end surface of the base portion 11a facing the −X direction is exposed on the side surface of the transparent resin body 17 facing the −X direction; and the end surface of the base portion 12a facing the +X direction is exposed on the side surface of the transparent resin body 17 facing the +X direction. The recesses 11w and 12w are made in the leadframes 11 and 12 respectively between the exposed regions of the lower surfaces and the exposed regions of the end surfaces; and the inner surfaces of the recesses 11w and 12w are not covered with the transparent resin body 17.

The recesses 11w and 12w are formed between the lower surface and the side surfaces of both of the longitudinal-direction end portions of the rectangular parallelepiped of the exterior form of the LED package 1. The upper surface of the LED package 1 includes the upper surface of the transparent resin body 17; the side surfaces of the LED package 1 include the side surfaces of the transparent resin body 17 and a portion of the end surfaces of the leadframes 11 and 12; and the lower surface of the LED package 1 includes the lower surface of the transparent resin body 17 and a portion of the lower surfaces of the leadframes 11 and 12. Thus, the exterior surface of the portion of the LED package 1 other than the recesses 11w and 12w includes the surfaces of the transparent resin body 17 and the exposed regions of the leadframes 11 and 12 exposed on the lower surface and the side surfaces of the transparent resin body 17; and the configuration thereof is a rectangular parallelepiped.

Many phosphors (not illustrated) are dispersed in the interior of the transparent resin body 17. Each of the phosphors has a granular configuration and is configured to absorb the light emitted from the LED chip 14 and emit light of a longer wavelength. For example, the phosphor absorbs a portion of the blue light emitted from the LED chip 14 and emits yellow light. Thereby, the LED package 1 emits the blue light that is emitted by the LED chip 14 and not absorbed into the phosphor and the yellow light emitted from the phosphor, and the emitted light as an entirety is white.

A method for manufacturing the LED package according to the embodiment will now be described.

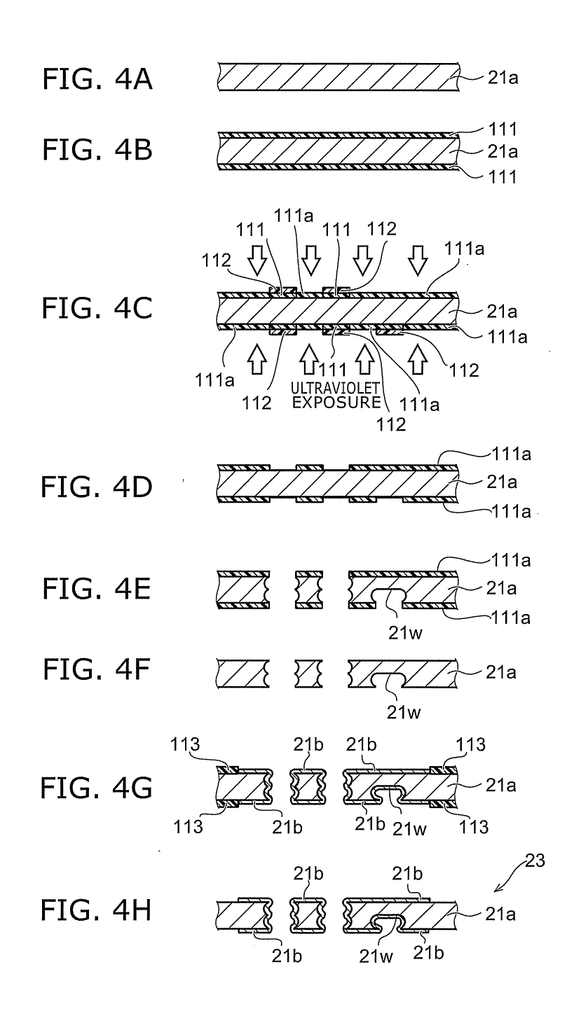

FIGS. 4A to 4H are cross-sectional views of processes, illustrating the method for forming the leadframe sheet of the embodiment.

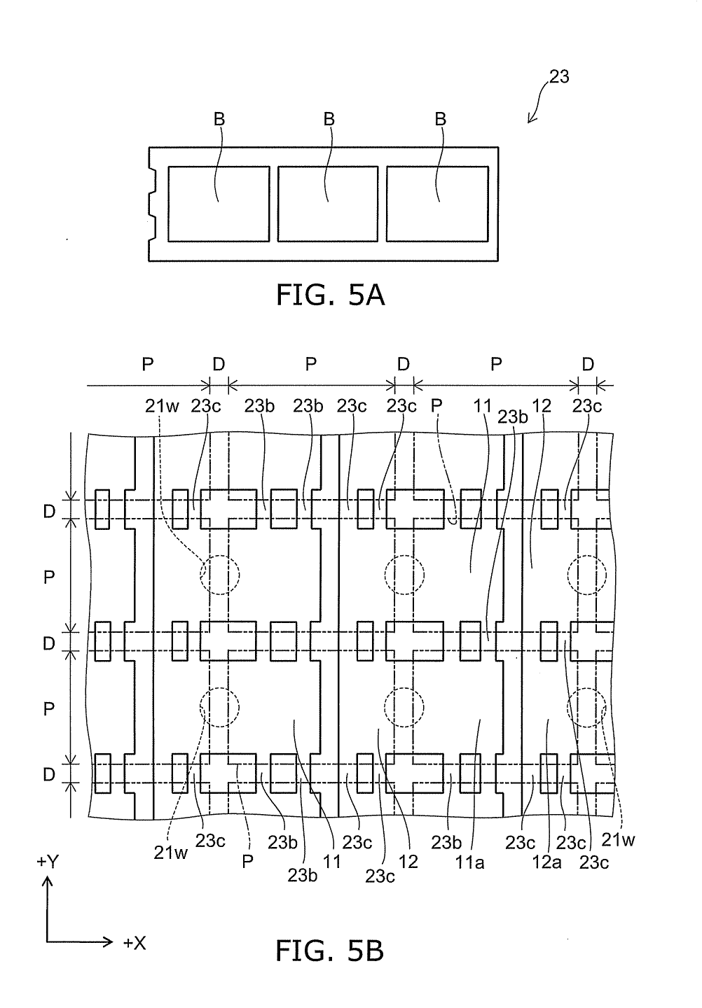

FIG. 5A is a plan view illustrating the leadframe sheet of the embodiment; and FIG. 5B is a partially-enlarged plan view illustrating device regions of the leadframe sheet.

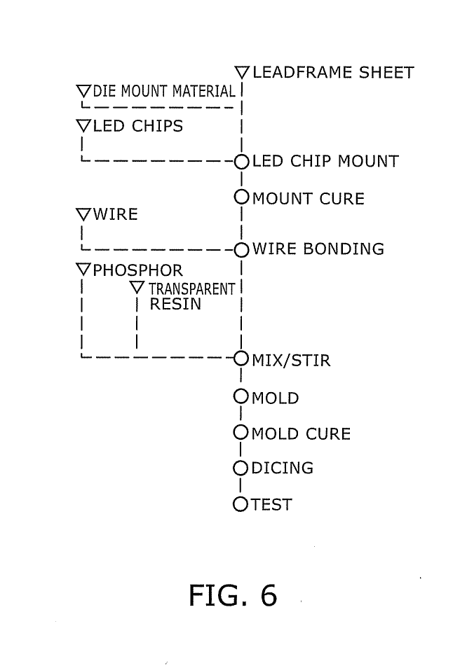

FIG. 6 is a flowchart illustrating the method for manufacturing the LED package according to the embodiment.

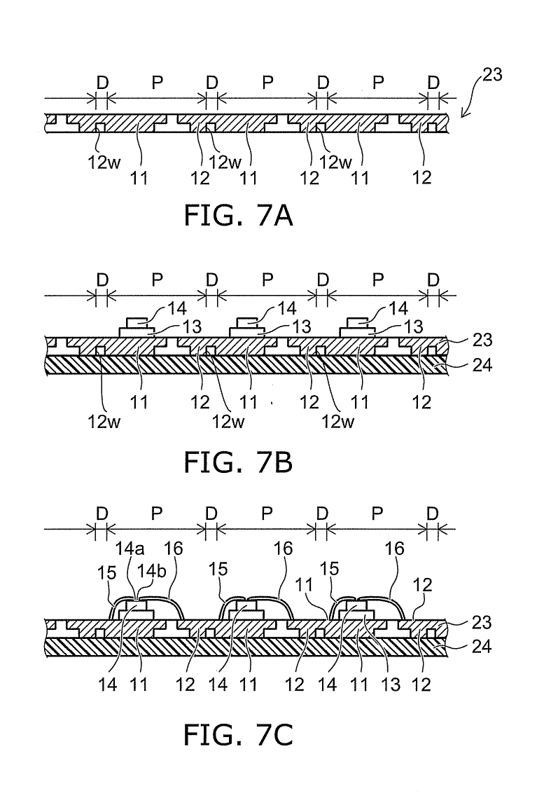

FIGS. 7A to 7C are cross-sectional views of processes, illustrating the method for manufacturing the LED package according to the embodiment.

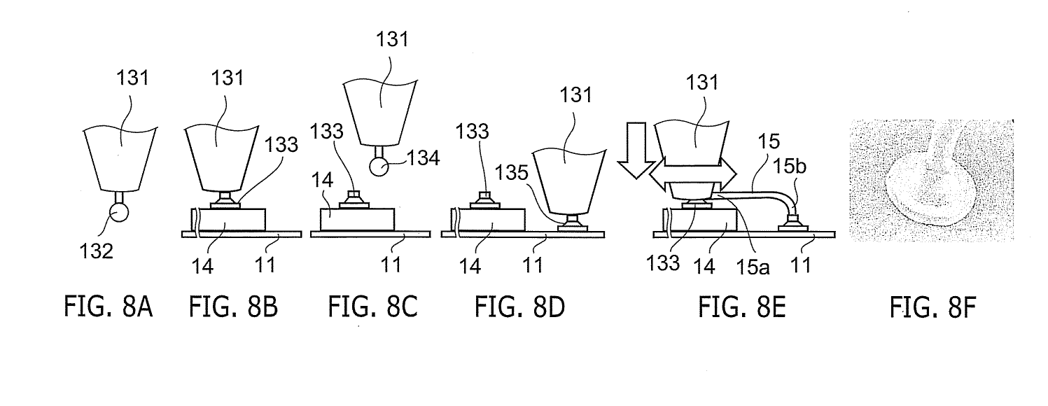

FIGS. 8A to 8F are cross-sectional views of processes, illustrating the wire bonding method of the embodiment.

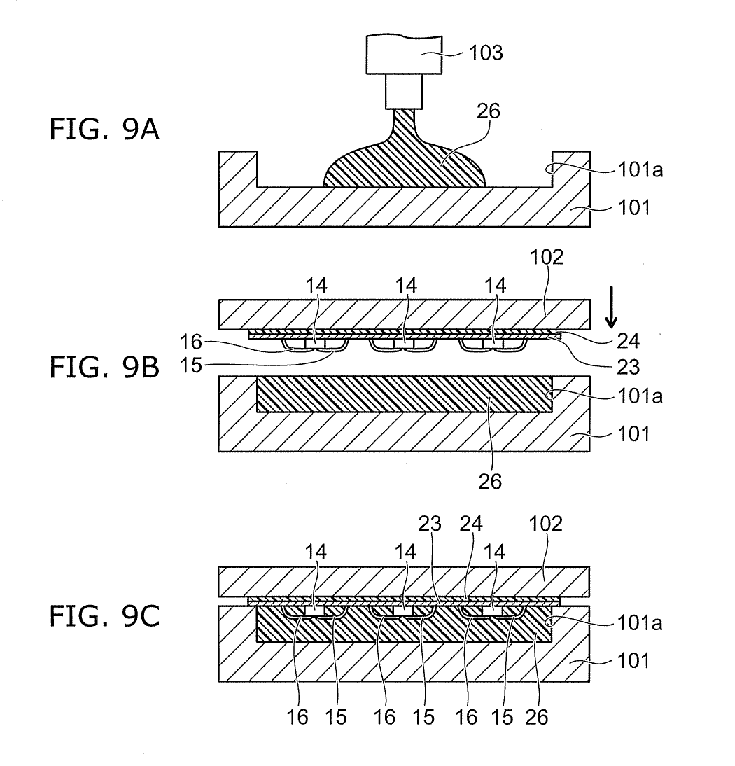

FIGS. 9A to 9C are cross-sectional views of processes, illustrating the method for manufacturing the LED package according to the embodiment.

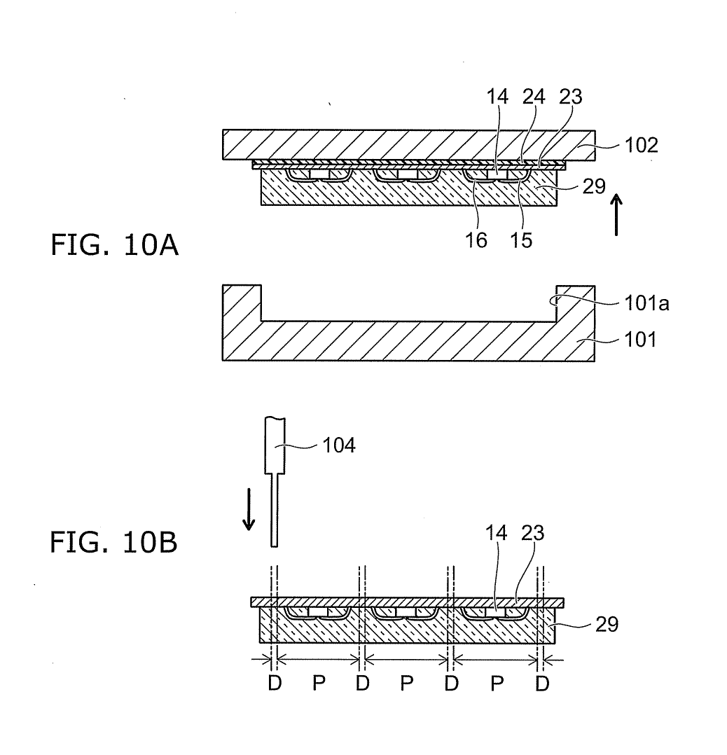

FIGS. 10A and 10B are cross-sectional views of processes, illustrating the method for manufacturing the LED package according to the embodiment.

First, as illustrated in FIG. 4A, a copper plate 21a is prepared and cleaned. Then, as illustrated in FIG. 4B, a resist film 111 is formed by performing resist coating on both surfaces of the copper plate 21a and by subsequently drying. Then, as illustrated in FIG. 4C, a mask pattern 112 is disposed on the resist film 111 and is exposed by irradiating ultraviolet. Thereby, the exposed portions of the resist film 111 are cured; and a resist mask 111a is formed. Then, as illustrated in FIG. 4D, developing is performed; and the uncured portions of the resist film 111 are rinsed away. Thereby, the resist pattern 111a remains on the upper surface and the lower surface of the copper plate 21a.

Then, as illustrated in FIG. 4E, the exposed portions of the copper plate 21a are selectively removed from both surfaces by performing etching using the resist pattern 111a as a mask. At this time, the etching depth is about half of the plate thickness of the copper plate 21a. Thereby, the regions etched only from one surface side are half-etched; and the regions etched from both surface sides are pierced. A recess 21w is made by half-etching of the lower surface of the copper plate 21a from the lower surface side. The recess 21w has, for example, a hemispherical configuration. However, the configuration of the recess 21w is not limited to a hemispherical configuration. It is sufficient for the recess 21w to be covered with a plating layer such as a silver plating layer 21b, etc., in the process illustrated in FIG. 4F and for there to be an affinity to a bonding material such as solder, etc., when mounting the completed LED package 1 to the motherboard. For example, the configuration of the recess 21w may be a semicylindrical column or a rectangular parallelepiped.

Continuing as illustrated in FIG. 4F, the resist pattern 111a is removed. Then, as illustrated in FIG. 4G, the end portions of the copper plate 21a are covered with a mask 113; and plating of another conductive material different from copper, e.g., silver or palladium, e.g., silver is performed. Thereby, a silver plating layer 21b is formed on the surfaces of the portions of the copper plate 21a other than the end portions. At this time, the silver plating layer 21b is formed also in the half-etched regions; and the inner surface of the recess 21w also is covered with the silver plating layer 21b.

Then, as illustrated in FIG. 4H, the mask 113 is removed by cleaning. Subsequently, an inspection is performed. Thus, a leadframe sheet 23 is constructed as illustrated in FIG. 4H, FIGS. 5A and 5B, FIG. 6, and FIG. 7A. For convenience of illustration in FIG. 7A and subsequent drawings, the copper plate 21a and the silver plating layer 21b are illustrated integrally as the leadframe sheet 23 without being discriminated.

In the leadframe sheet 23 as illustrated in FIG. 5A, for example, three blocks B are set; and, for example, about 1000 device regions P are set in each of the blocks B. As illustrated in FIG. 5B, the device regions P are arranged in a matrix configuration; and the region between the device regions P is used as a dicing region D having a lattice configuration. A basic pattern including the mutually-separated leadframes 11 and 12 is formed in each of the device regions P. Thick plate portions which are not etched and thin plate portions which are half-etched from the lower surface side are formed in each of the leadframes. In the dicing region D, a portion of the conductive material of the conductive sheet 21 is removed by the etching from both surface sides; and the remaining portion of the conductive material is etched from only the lower surface side to remain to link the mutually-adjacent device regions P to each other to form linking portions.

In other words, although the leadframe 11 and the leadframe 12 are separated from each other in the device region P, the leadframe 11 belonging to one of the device regions P is linked to the leadframe 12 belonging to the adjacent device region P positioned in the −X direction as viewed from the one of the device regions P. The recess 21w is made in the lower surface of the linking portion between the leadframe 11 and the leadframe 12. The leadframes 11 belonging to device regions P adjacent to each other in the Y direction are linked to each other via linking portions 23b. Similarly, the leadframe 12 belonging to device regions P adjacent to each other in the Y direction are linked to each other via linking portions 23c. Thereby, four linking portions extend from each of the base portions 11a and 12a of the leadframes 11 and 12.

Then, as illustrated in FIG. 6 and FIG. 7B, a reinforcing tape 24 made of, for example, polyimide is adhered to the lower surface of the leadframe sheet 23. At this time, the recess 21w is airtightly covered with the reinforcing tape 24. Then, the die mount material 13 is bonded to cover the leadframe 11 belonging to each of the device regions P of the leadframe sheet 23. For example, the die mount material 13 having a paste configuration may be dispensed onto the leadframe 11 from a dispenser or transferred onto the leadframe 11 using mechanical means. Then, the LED chip 14 is mounted on the die mount material 13. Continuing, heat treatment (mount cure) is performed to cure the die mount material 13. Thereby, the LED chip 14 is mounted via the die mount material 13 on the leadframe 11 of each of the device regions P of the leadframe sheet 23.

Continuing as illustrated in FIG. 6 and FIG. 7C, one end of the wire 15 is bonded to the terminal 14a of the LED chip 14 and the other end is bonded to the upper surface 11u of the leadframe 11 using, for example, ultrasonic bonding. One end of the wire 16 is bonded to the terminal 14b of the LED chip 14 and the other end is bonded to the upper surface 12u of the leadframe 12. Thereby, the terminal 14a is connected to the leadframe 11 via the wire 15; and the terminal 14b is connected to the leadframe 12 via the wire 16.

A method for bonding the wire 15 to the terminal 14a and the leadframe 11 will now be described in detail. The method for bonding the wire 16 also is similar.

As illustrated in FIG. 8A, a ball 132 made of a bonding material is formed at the tip of a capillary 131. Then, as illustrated in FIG. 8B, the ball 132 is pressed onto the upper surface of the LED chip 14 by moving the capillary 131. Thereby, a bump 133 is formed on the upper surface of the LED chip 14. Then, as illustrated in FIG. 8C, the capillary 131 is separated from the LED chip 14 without winding out the wire. Continuing, a new ball 134 is formed at the tip of the capillary 131. Then, as shown in FIG. 8D, the ball 134 is pressed onto the upper surface of the leadframe 11. Thereby, a bump 135 is formed on the upper surface of the leadframe 11.

Then, as illustrated in FIG. 8E, the capillary 131 is moved once substantially upward while winding out the wire 15 from the tip of the capillary 131; and then the tip of the capillary 131 reaches the bump 133 on the LED chip 14 by moving in a substantially horizontal direction. At this time, the end portion 15b of the wire 15 remains bonded to the leadframe 11 via the bump 135. Thereby, the wire 15 drawn out from the bump 135 is curved toward the horizontal direction. Then, a second bonding is performed using the capillary 131 by applying a load and ultrasonic waves to the bump 133. Thereby, the end portion 15a of the wire 15 is bonded to the LED chip 14 via the bump 133. Thus, the wire 15 is connected between the leadframe 11 and the LED chip 14. In the case where the wire is bonded by this method, bumps such as that illustrated in FIG. 8F are formed at both the bonding portion between the leadframe 11 and the wire 15 and the bonding portion between the LED chip 14 and the wire 15, i.e., both of the end portions of the wire 15.

Then, as illustrated in FIG. 6 and FIG. 9A, a lower die 101 is prepared. The lower die 101 is included in one die set with an upper die 102 described below; and a recess 101a having a rectangular parallelepiped configuration is made in the upper surface of the lower die 101. On the other hand, a liquid or semi-liquid phosphor-containing resin material 26 is prepared by mixing a phosphor into a transparent resin such as a silicone resin and stirring. Then, the phosphor-containing resin material 26 is supplied to the recess 101a of the lower die 101 using a dispenser 103.

Continuing as illustrated in FIG. 6 and FIG. 9B, the leadframe sheet 23 on which the LED chips 14 described above are mounted is mounted to the lower surface of the upper die 102 such that the LED chips 14 face downward. Then, the die is closed by pressing the upper die 102 onto the lower die 101. Thereby, the upper surface of the leadframe sheet 23 is pressed onto the phosphor-containing resin material 26. At this time, the phosphor-containing resin material 26 covers the LED chips 14 and the wires 15 and 16 and enters also into the portion of the leadframe sheet 23 removed by the etching. However, the phosphor-containing resin material 26 does not enter the recess 21w because the recess 21w is airtightly covered with the reinforcing tape 24. Thus, the phosphor-containing resin material 26 is molded. It is favorable for this mold process to be implemented in a vacuum atmosphere. Thereby, the bubbles occurring in the phosphor-containing resin material 26 can be prevented from adhering to the half-etched portions of the leadframe sheet 23.

Then, as illustrated in FIG. 6 and FIG. 9C, heat treatment (mold cure) is performed in a state in which the upper surface of the leadframe sheet 23 is pressed onto the phosphor-containing resin material 26 to cure the phosphor-containing resin material 26. Subsequently, as illustrated in FIG. 10A, the upper die 102 is pulled away from the lower die 101. Thereby, a transparent resin plate 29 is formed on the leadframe sheet 23 to cover the entire upper surface and a portion of the lower surface of the leadframe sheet 23 to bury the LED chips 14, etc. The phosphor is dispersed in the transparent resin plate 29. Subsequently, the reinforcing tape 24 is peeled from the leadframe sheet 23. Thereby, the lower surfaces of the thick plate portions 11t and 12t of the leadframes 11 and 12 (referring to FIG. 2) are exposed on the surface of the transparent resin plate 29.

Continuing as illustrated in FIG. 6 and FIG. 10B, dicing is performed on the bonded body made of the leadframe sheet 23 and the transparent resin plate 29 from, for example, the leadframe sheet 23 side using a blade 104. Thereby, the portions of the leadframe sheet 23 and the transparent resin plate 29 disposed in the dicing region D are cut. As a result, the portions of the leadframe sheet 23 and the transparent resin plate 29 disposed in the device regions P are singulated; and the LED package 1 illustrated in FIG. 1 to FIG. 3 is manufactured.

The leadframes 11 and 12 are separated from the leadframe sheet 23 in each of the LED packages 1 after the dicing. The transparent resin plate 29 is divided to form the transparent resin body 17. At this time, the recess 21w is divided to make the recesses 11w and 12w in the leadframes 11 and 12 respectively. The extending portions 11b to 11e are formed in the leadframe 11 by the linking portions 23b being divided; and the extending portions 12b to 12e are formed in the leadframe 12 by the linking portions 23c being divided. The tip surfaces of the extending portions 11b to 11e and 12b to 12e are exposed on the side surfaces of the transparent resin body 17.

Then, as illustrated in FIG. 6, various tests are performed on the LED package 1. At this time, it is also possible to use the tip surfaces of the extending portions 11b to 11e and 12b to 12e as the terminals for the tests.

Operational effects of the embodiment will now be described.

Because a casing made of a white resin is not provided in the LED package 1 according to the embodiment, the casing does not degrade by absorbing the light and the heat generated by the LED chip 14. Although the degradation progresses easily particularly in the case where the casing is formed of a polyamide-based thermoplastic resin, there is no such risk in the embodiment. Therefore, the LED package 1 according to the embodiment has high durability. Accordingly, the LED package 1 according to the embodiment has a long life, high reliability, and is applicable to a wide range of applications.

In the LED package 1 according to the embodiment, the recess 11w is made in the leadframe 11; and the recess 12w is made in the leadframe 12. Thereby, the leadframes 11 and 12 can be connected reliably to the pads of a motherboard (not illustrated) by a bonding material such as solder, etc., being filled into the recesses 11w and 12w when mounting the LED package 1 to the motherboard. In other words, the recesses 11w and 12w function as side surface solder fillets of the LED package 1. The adhesion of the bonding material is good because the inner surface of the recess 11w and the inner surface of the recess 12w are covered with a silver plating layer or a palladium plating layer. As a result, the LED package 1 according to the embodiment has high long-term reliability after being mounted to the motherboard.

In the LED package 1 according to the embodiment, the leadframes 11 and 12 can be held better by the lower surfaces of the thin plate portions 11s and 12s being covered with the transparent resin body 17 while realizing the external electrode pads by exposing the lower surfaces of the thick plate portions 11t and 12t of the leadframes 11 and 12 from the transparent resin body 17. The leadframes 11 and 12 can be securely held particularly by the mutually-opposing portions of the leadframes 11 and 12 being used as the thin plate portions and by the lower surfaces of the thin plate portions being covered with the transparent resin body 17. Thereby, the leadframes 11 and 12 do not easily peel from the transparent resin body 17 during the dicing; and the yield of the LED package 1 can be increased.

In the LED package 1 according to the embodiment, the transparent resin body 17 is formed of a silicone resin. The durability of the LED package 1 also increases because the silicone resin has high durability to the light and the heat.

In the LED package 1 according to the embodiment, the light is emitted toward a wide angle because a casing covering the side surface of the transparent resin body 17 is not provided. Therefore, the LED package 1 according to the embodiment is advantageous when used in applications in which it is necessary for the light to be emitted at a wide angle, e.g., the backlight of a liquid crystal display apparatus and illumination.

Furthermore, in the embodiment, many, e.g., about several thousand, LED packages 1 can be collectively manufactured from one conductive sheet 21. Thereby, the manufacturing cost per LED package 1 can be reduced. The number of parts, the number of processes, and the costs are low because the casing is not provided.

In the embodiment, the leadframe sheet 23 is formed using wet etching. Therefore, it is sufficient to prepare only the form of the masks when manufacturing the LED package with a new layout; and the initial cost can be kept lower than that of the case where the leadframe sheet 23 is formed using a method such as stamping with a die, etc.

In the LED package 1 according to the embodiment, the extending portions extend from the base portions 11a and 12a of the leadframes 11 and 12. Thereby, the exposed surface area of the leadframes 11 and 12 can be reduced. As a result, the leadframes 11 and 12 can be prevented from peeling from the transparent resin body 17. Corrosion of the leadframes 11 and 12 also can be suppressed.

Considering these effects from the aspect of the manufacturing method, the metal portions interposed in the dicing region D are reduced by providing the linking portions 23b and 23c to be interposed in the dicing region D of the leadframe sheet 23 as illustrated in FIG. 5B. Thereby, the dicing is easier; and wear of the dicing blade can be suppressed. In the leadframe sheet 23, the leadframe 11 is linked to the leadframe 12 with the dicing region D interposed; the leadframes 11 are linked to each other by the linking portions 23b; and the leadframes 12 are linked to each other by the linking portions 23c. Thereby, the mountability is high because the leadframe 11 is reliably supported from the three directions by the leadframes 11 and 12 of the adjacent device regions P in the mount process of the LED chip 14 illustrated in FIG. 7B. Similarly, in the wire bonding process illustrated in FIG. 7C as well, for example, there is not much loss of the ultrasonic waves applied during the ultrasonic bonding and good bonding of the wires to the leadframes and the LED chip can be provided because the bonding positions of the wires are reliably supported from the three directions.

In the embodiment, the dicing is performed from the leadframe sheet 23 side in the dicing process illustrated in FIG. 10B. Thereby, the conductive material of the cutting end portions of the leadframes 11 and 12 elongates over the side surface of the transparent resin body 17 in the +Z direction. Therefore, this conductive material does not elongate over the side surface of the transparent resin body 17 in the −Z direction to protrude from the lower surface of the LED package 1; and burrs do not occur. Accordingly, mounting defects due to burrs do not occur when mounting the LED package 1.

A second embodiment will now be described.

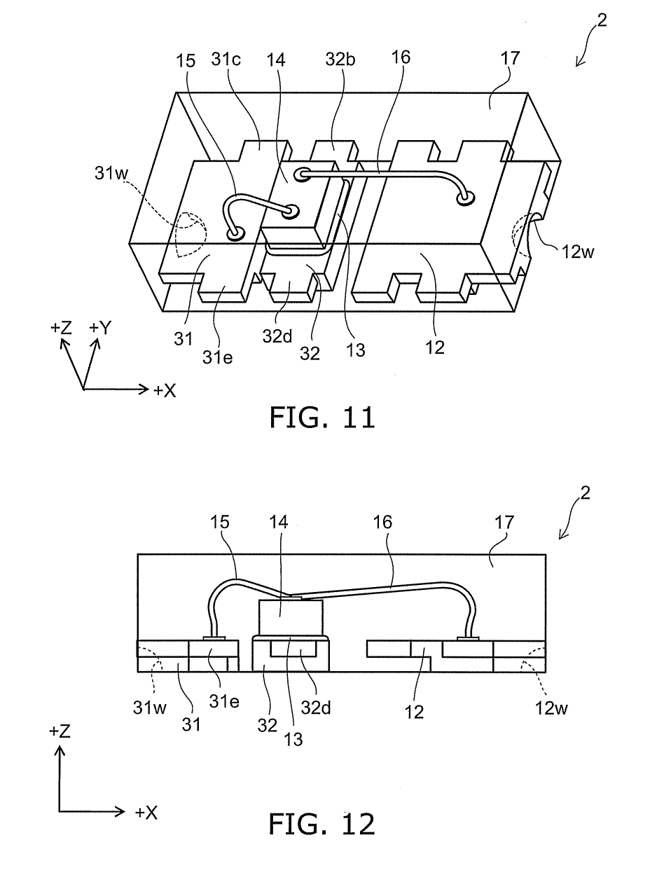

FIG. 11 is a perspective view illustrating the LED package according to the embodiment.

FIG. 12 is a side view illustrating the LED package according to the embodiment.

As illustrated in FIG. 11 and FIG. 12, the LED package 2 according to the embodiment differs from the LED package 1 according to the first embodiment described above (referring to FIG. 1) in that the leadframe 11 (referring to FIG. 1) is subdivided into two leadframes 31 and 32 in the X direction. The leadframe 32 is disposed between the leadframe 31 and the leadframe 12.

A recess 31w corresponding to the recess 11w of the leadframe 11 (referring to FIG. 1) is made in the leadframe 31. In the leadframe 31, extending portions 31c and 31e corresponding to the extending portions 11c and 11e of the leadframe 11 (referring to FIG. 1) are formed. On the other hand, in the leadframe 32, extending portions 32b and 32d corresponding to the extending portions 11b and 11d of the leadframe 11 (referring to FIG. 1) are formed. The entire base portion of the leadframe 32 is the thick plate portion; and the lower surface thereof is exposed on the lower surface of the transparent resin body 17. The extending portions 32b and 32d are the thin plate portions: and only the tip surfaces thereof are exposed on the side surfaces of the transparent resin body 17. Thus, a portion of the lower surface and a portion of the end surface of the leadframe 32 are exposed from the transparent resin body 17.

The LED chip 14 is mounted to the leadframe 32 via the die mount material 13; and the wire 15 is connected to the leadframe 31. Accordingly, the LED chip 14 is held by the leadframe 32 and is connected between the leadframe 31 and the leadframe 12.

In the embodiment, the leadframes 31 and 12 function as external electrodes by potentials being applied from the outside. On the other hand, it is unnecessary to apply a potential to the leadframe 32; and the leadframe 32 can be used as a dedicated heat sink leadframe. Thereby, the leadframe 32 can be connected to a common heat sink in the case where multiple LED packages 2 are mounted to one module. As a result, the LED package 2 according to the embodiment is advantageous in the aspect of heat dissipation. The grounding potential may be applied to the leadframe 32; and the leadframe 32 may be in a floating state.

Such an LED package 2 can be manufactured by a method similar to that of the first embodiment described above by modifying the basic pattern of each of the device regions P of the leadframe sheet 23 in the process illustrated in FIG. 4C described above. In other words, according to the manufacturing method described in the first embodiment described above, LED packages of various layouts can be manufactured by merely modifying the pattern of the resist mask 111a. Otherwise, the configuration, the manufacturing method, and the operational effects of the embodiment are similar to those of the first embodiment described above.

A third embodiment of the invention will now be described.

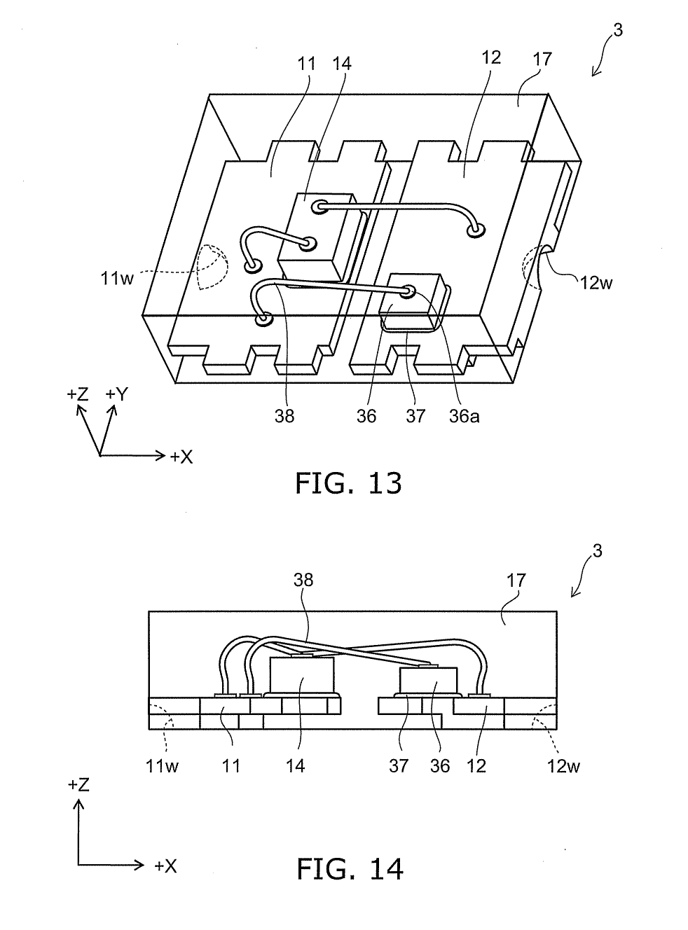

FIG. 13 is a perspective view illustrating the LED package according to the embodiment.

FIG. 14 is a side view illustrating the LED package according to the embodiment.

As illustrated in FIG. 13 and FIG. 14, a Zener diode chip 36 and the like is provided in the LED package 3 according to the embodiment and is connected between the leadframe 11 and the leadframe 12. In other words, a die mount material 37 made of a conductive material such as solder, a silver paste, etc., is bonded to cover the upper surface of the leadframe 12; and the Zener diode chip 36 is provided thereon. Thereby, the Zener diode chip 36 is mounted on the leadframe 12 via the die mount material 37; and the lower surface terminal (not illustrated) of the Zener diode chip 36 is connected to the leadframe 12 via the die mount material 37. An upper surface terminal 36a of the Zener diode chip 36 is connected to the leadframe 11 via a wire 38. In other words, one end of the wire 38 is connected to the upper surface terminal 36a of the Zener diode chip 36; and the other end of the wire 38 is bonded to the upper surface of the leadframe 11.

Thereby, in the embodiment, the Zener diode chip 36 can be connected in parallel with the LED chip 14. As a result, the resistance to ESD (Electrostatic Discharge) improves. Otherwise, the configuration, the manufacturing method, and the operational effects of the embodiment are similar to those of the first embodiment described above.

A fourth embodiment of the invention will now be described.

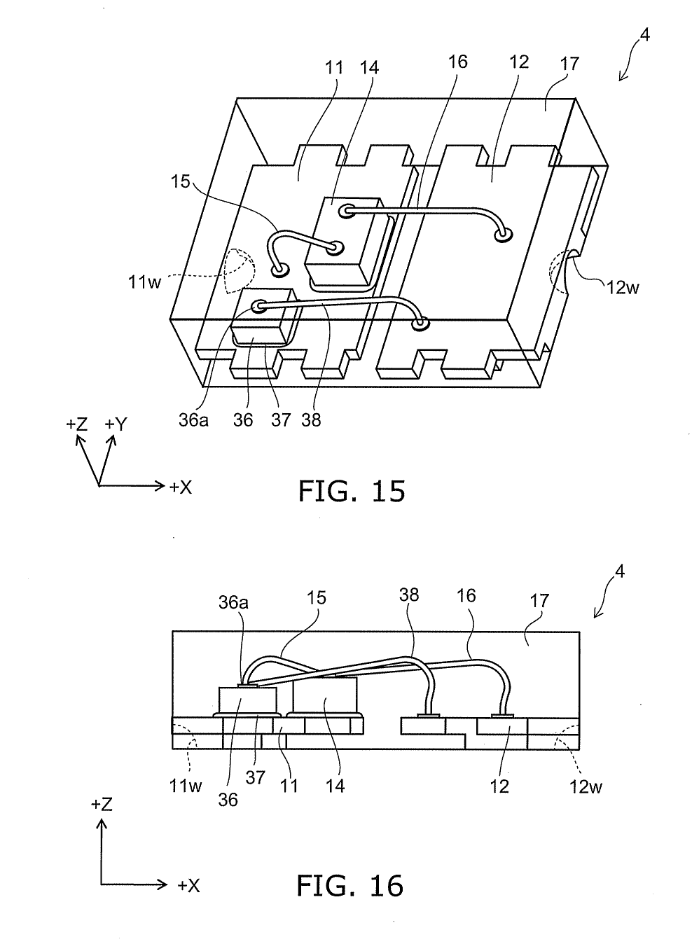

FIG. 15 is a perspective view illustrating the LED package according to the embodiment.

FIG. 16 is a side view illustrating the LED package according to the embodiment.

As illustrated in FIG. 15 and FIG. 16, the LED package 4 according to the embodiment differs from the LED package 3 according to the fourth embodiment described above (referring to FIG. 13) in that the Zener diode chip 36 is mounted to the leadframe 11. In this case, the lower surface terminal of the Zener diode chip 36 is connected to the leadframe 11 via the die mount material 37; and the upper surface terminal 36a is connected to the leadframe 12 via the wire 38. Otherwise, the configuration, the manufacturing method, and the operational effects of the embodiment are similar to those of the third embodiment described above.

A fifth embodiment of the invention will now be described.

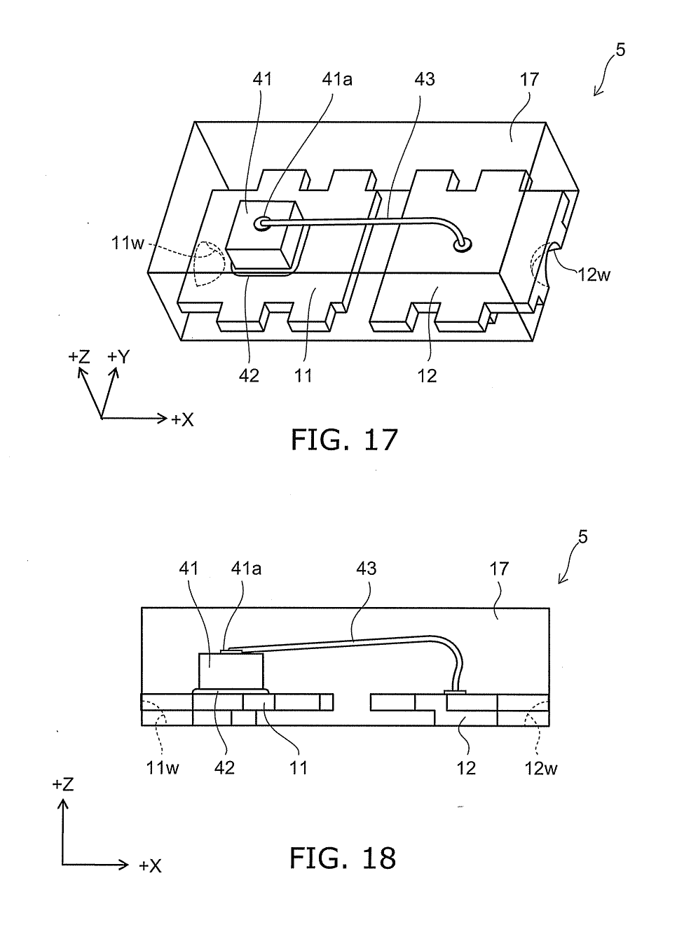

FIG. 17 is a perspective view illustrating the LED package according to the embodiment.

FIG. 18 is a side view illustrating the LED package according to the embodiment.

As illustrated in FIG. 17 and FIG. 18, the LED package 5 according to the embodiment differs from the LED package 1 according to the first embodiment described above (referring to FIG. 1) in that a vertically-conducting LED chip 41 is provided instead of the upper surface terminal-type LED chip 14. In other words, in the LED package 5 according to the embodiment, a die mount material 42 made of a conductive material such as solder, a silver paste, etc., is formed on the upper surface of the leadframe 11; and the LED chip 41 is mounted via the die mount material 42. Then, the lower surface terminal (not illustrated) of the LED chip 41 is connected to the leadframe 11 via the die mount material 42. On the other hand, an upper surface terminal 41a of the LED chip 41 is connected to the leadframe 12 via a wire 43.

By employing the vertically-conducting LED chip 41 and by using one wire in the embodiment, contact between the wires can be reliably prevented; and the wire bonding process can be simplified. Otherwise, the configuration, the manufacturing method, and the operational effects of the embodiment are similar to those of the first embodiment described above.

A sixth embodiment of the invention will now be described.

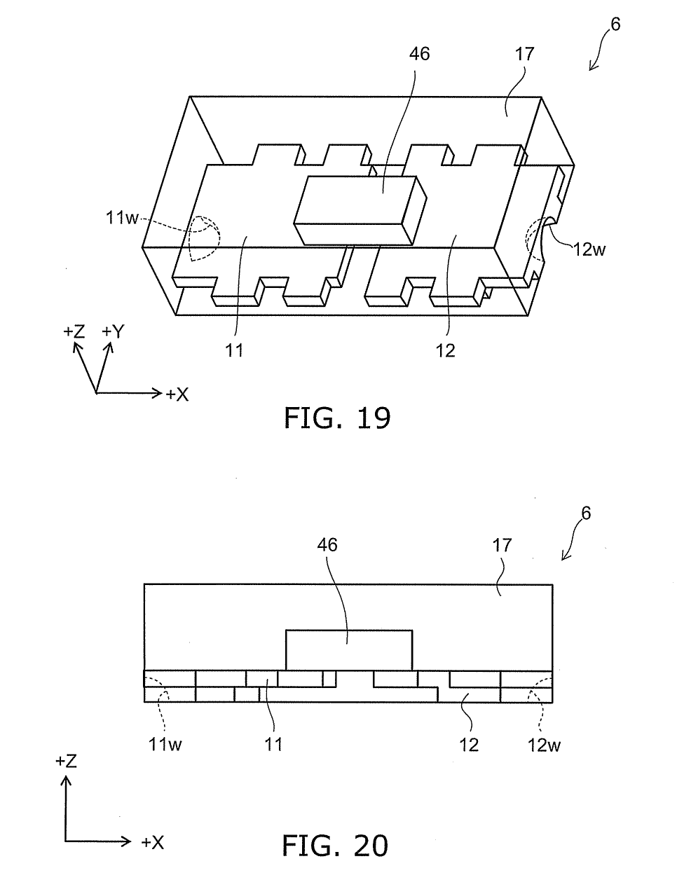

FIG. 19 is a perspective view illustrating the LED package according to the embodiment.

FIG. 20 is a side view illustrating the LED package according to the embodiment.

As illustrated in FIG. 19 and FIG. 20, the LED package 6 according to the embodiment differs from the LED package 1 according to the first embodiment described above (referring to FIG. 1) in that a flipped LED chip 46 is provided instead of the upper surface terminal-type LED chip 14. In other words, in the LED package 6 according to the embodiment, two terminals (not illustrated) are provided in the lower surface of the LED chip 46. The LED chip 46 is disposed in a bridge configuration to straddle the leadframe 11 and the leadframe 12 from a region directly above the leadframe 11 to a region directly above the leadframe 12. Then, one lower surface terminal of the LED chip 46 is connected to the leadframe 11; and the other lower surface terminal is connected to the leadframe 12.

Because the wires are eliminated by employing the flipped LED chip 46 in the embodiment, the upward light extraction efficiency can be increased and the wire bonding process can be omitted. Also, breakage of the wires due to the thermal stress of the transparent resin body 17 can be prevented. Otherwise, the configuration, the manufacturing method, and the operational effects of the embodiment are similar to those of the first embodiment described above.

A seventh embodiment of the invention will now be described.

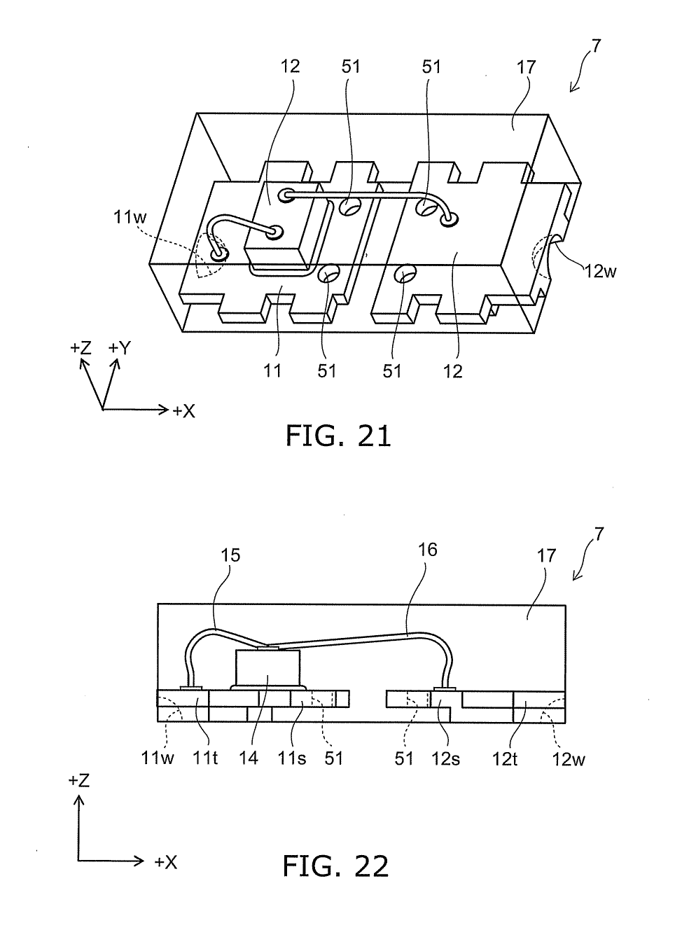

FIG. 21 is a perspective view illustrating the LED package according to the embodiment.

FIG. 22 is a side view illustrating the LED package according to the embodiment.

As illustrated in FIG. 21 and FIG. 22, the LED package 7 according to the embodiment differs from the LED package 1 according to the first embodiment described above (referring to FIG. 1) in that through-holes 51 are made in the thin plate portion 11s of the leadframe 11 and the thin plate portion 12s of the leadframe 12. The through-holes 51 are made, for example, in two locations in each of the mutually-opposing portions of the leadframes 11 and 12. However, the formation position and the number of the through-holes 51 is not limited thereto. It is sufficient for the through-holes 51 to be made in the thin plate portions of the leadframes. The through-holes 51 pierce the thin plate portions 11s and 12s in the thickness direction (the Z direction) thereof; and the transparent resin body 17 enters the interiors of the through-holes 51.

According to the embodiment, the contact surface area between the leadframes 11 and 12 and the transparent resin body 17 is large and the leadframes 11 and 12 have good adhesion with the transparent resin body 17 because the through-holes 51 are made in the leadframes 11 and 12. The portions of the transparent resin body 17 disposed above the leadframes 11 and 12 are linked to the portions of the transparent resin body 17 disposed below the leadframes 11 and 12 via the portions of the transparent resin body 17 filled into the through-holes 51. Thereby, the through-holes 51 function as anchor holes to increase the structural strength of the transparent resin body 17 and hold the leadframes 11 and 12 better. Otherwise, the configuration, the manufacturing method, and the operational effects of the embodiment are similar to those of the first embodiment described above.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. The above embodiments can be practiced in combination with each other.

Although an example is illustrated in, for example, the first embodiment described above in which the leadframe sheet 23 is formed using wet etching, the invention is not limited thereto. For example, mechanical means such as a press, etc., may be used. Although an example is illustrated in the first embodiment described above in which silver plating layers are formed on the upper surface and the lower surface of the copper plate of a leadframe, the invention is not limited thereto. For example, silver plating layers may be formed on the upper surface and the lower surface of the copper plate; and a rhodium (Rh) plating layer may be formed on at least one of the silver plating layers. A copper (Cu) plating layer may be formed between the copper plate and the silver plating layers. Nickel (Ni) plating layers may be formed on the upper surface and the lower surface of the copper plate; and a plating layer of an alloy of gold and silver (a Au—Ag alloy) may be formed on the nickel plating layers.

Although an example is illustrated in the embodiments described above in which the LED chip is configured to emit blue light, the phosphor is configured to absorb the blue light and emit yellow light, and the color of the light emitted from the LED package is white, the invention is not limited thereto. The LED chip may be configured to emit visible light of a color other than blue and may be configured to emit ultraviolet or infrared. The phosphor is not limited to a phosphor configured to emit yellow light and may be a phosphor configured to emit, for example, blue light, green light, or red light. The color of the light that the entire LED package emits is not limited to white. Any color tone can be realized by adjusting the weight ratio R:G:B of the red phosphor, the green phosphor, and the blue phosphor such as those described above. The phosphor may not be provided in the LED package. In such a case, the light emitted from the LED chip is emitted from the LED package.

Although an example is illustrated in the embodiments described above in which the configuration of the base portion of the leadframe is rectangular as viewed from above, the base portion may have a configuration in which at least one corner is removed. Thereby, such corners do not become starting points of the resin peeling and/or cracks because the right angles or acute angles proximal to the corner of the LED package are removed. As a result, the occurrence of the resin peeling and/or cracks can be suppressed for the LED package as an entirety.

According to the embodiments described above, an LED package having high durability and low costs and a method for manufacturing the same can be realized.

What is claimed is:

1. An LED package, comprising:
a first leadframe and a second leadframe mutually-separated;
an LED chip provided above the first leadframe and the second leadframe, one terminal of the LED chip being connected to the first leadframe, one other terminal of the LED chip being connected to the second leadframe; and
a resin body covering an entire upper surface, a portion of a lower surface, and a portion of an end surface of the first leadframe and an entire upper surface, a portion of a lower surface, and a portion of an end surface of the second leadframe, the resin body covering the LED chip, a remaining portion of the lower surface of the first leadframe and a remaining portion of the end surface of the first leadframe being exposed on the resin body, a remaining portion of the lower surface of the second leadframe and a remaining portion of the end surface of the second leadframe being exposed on the resin body,
a first recess being made between the remaining portion of the lower surface of the first leadframe and the remaining portion of the end surface of the first leadframe, a second recess being made between the remaining portion of the lower surface of the second leadframe and the remaining portion of the end surface of the second leadframe, an inner surface of each of the first recess and the second recess being not covered with the resin body.

2. The package according to claim 1, wherein the inner surface of the first recess, the upper surface and the lower surface of the first leadframe, the inner surface of the second recess, and the upper surface and the lower surface of the second leadframe are covered with a plating layer made of one conductive material, and an end surface of the first leadframe and an end surface of the second leadframe are not covered with the plating layer.

3. The package according to claim 2, wherein main bodies of the first and second leadframes are made of copper, and the plating layer is made of silver or palladium.

4. The package according to claim 1, wherein
the LED package have a rectangular parallelepiped configuration, if the first recess and the second recess were not made,
an upper surface of the LED package is formed of an upper surface of the resin body,
side surfaces of the LED package are formed of side surfaces of the resin body, the remaining portion of the end surface of the first leadframe and the remaining portion of the end surface of the second leadframe;
a lower surface of the LED package is formed of a lower surface of the resin body, the remaining portion of the lower surface of the first leadframe and the remaining portion of the lower surface of the second leadframe, and
the first recess and the second recess are formed between the lower surface of the rectangular parallelepiped and the side surfaces of the rectangular parallelepiped at two longitudinal-direction end portions.

5. The package according to claim 1, wherein
each of the first leadframe and the second leadframe includes:
a thick plate portion having a lower surface exposed on a lower surface of the resin body; and
a thin plate portion having a lower surface covered with the resin body, the thin plate portion is thinner than the thick plate portion,
each of the first recess and the second recess are made in the thick plate portion.

6. The package according to claim 5, wherein each of mutually-opposing portions of the first leadframe and the second leadframe is the thin plate portion.

7. The package according to claim 5, wherein
a through-hole is made in the thin plate portion to pierce the thin plate portion in the thickness direction, and
the resin body enters the through-hole.

8. The package according to claim 1, wherein a configuration of each of the first recess and the second recess is a portion of a sphere.

9. The package according to claim 1, further comprising:
a first wire connecting the one terminal to the first leadframe; and
a second wire connecting the one other terminal to the second leadframe,
the LED chip being mounted to the first leadframe,
both the one terminal and the one other terminal being provided in an upper surface of the LED chip.

10. The package according to claim 1, further comprising:
a first wire connecting the one terminal to the first leadframe;
a second wire connecting the one other terminal to the second leadframe; and
a third leadframe disposed between the first leadframe and the second leadframe, a portion of a lower surface and a portion of an end surface of the third leadframe being exposed on the resin body,
the LED chip being mounted to the third leadframe,
both the one terminal and the one other terminal being provided in an upper surface of the LED chip.

11. The package according to claim 1, further comprising:
a die mount material affixing the LED chip to the first leadframe while connecting the one terminal to the first leadframe, the die mount material being made of a conductive material; and
a wire connecting the one other terminal to the second leadframe,
the LED chip being mounted to the first leadframe,
the one terminal being provided in a lower surface of the LED chip, the one other terminal being provided in an upper surface of the LED chip.

12. The package according to claim 1, wherein:
the LED chip is disposed from a region directly above the first leadframe to a region directly above the second leadframe; and
both the one terminal and the one other terminal are provided in a lower surface of the LED chip.

13. The package according to claim 1, further comprising a Zener diode chip connected between the first leadframe and the second leadframe.

14. A method for manufacturing an LED package, comprising:
forming a leadframe sheet made of a conductive material and including a plurality of device regions arranged in a matrix configuration, a basic pattern including a first leadframe and the second leadframe mutually-separated being formed in each of the device regions, a plurality of linking portions being provided in a dicing region between the device regions to extend from the basic pattern through the dicing region to the basic pattern of an adjacent device region, a recess being made in a lower surface of each of the linking portions;
adhering a reinforcing tape to a lower surface of the leadframe sheet to cover the recess;
mounting an LED chip on an upper surface of the leadframe sheet in each of the device regions, connecting one terminal of the LED chip to the first leadframe, and connecting one other terminal of the LED chip to the second leadframe;
causing the upper surface of the leadframe sheet to contact a liquid or semi-liquid resin held by a template to cause the resin to enter a gap made by removing the conductive material, the gap not including the recess;
forming a resin plate by curing the resin;
peeling the reinforcing tape from the leadframe sheet; and
dividing the recess while singulating portions of the leadframe sheet and the resin plate disposed in the device region by cutting portions of the leadframe sheet and the resin plate disposed in the dicing region.

15. The method according to claim 14, wherein the forming the leadframe sheet includes forming a plating layer on a surface of the leadframe sheet, the plating layer being made of one other conductive material different from the conductive material.

16. The method according to claim 15, wherein the conductive material is copper, and the one other conductive material is silver or palladium.

17. The method according to claim 14, wherein a conductive sheet made of the conductive material is selectively etched from an upper surface side and from a lower surface side and at least the etching from the lower surface side is stopped before piercing the conductive sheet in the forming the leadframe sheet.
